(19) United States
(12) Patent Application Publication
(10) Pub. No.: US 2025/0055298 A1
(43) Pub. Date: Feb. 13, 2025

(54) METHOD AND APPARATUS FOR CHARGING OR DISCHARGING A BATTERY SYSTEM

(71) Applicant: Volkswagen Aktiengesellschaft, Wolfsburg (DE)

(72) Inventors: Bjoern RUMBERG, Wolfenbuettel (DE); Tobias KLEIN, Wolfenbuettel (DE); Benjamin BEDUERFTIG, Ulm (DE)

(73) Assignee: Volkswagen Aktiengesellschaft, Wolfsburg (DE)

(21) Appl. No.: 18/797,314

(22) Filed: Aug. 7, 2024

(30) Foreign Application Priority Data
Aug. 7, 2023 (DE) 10 2023 207 541.5

(51) Int. Cl. H02J 7/00; H01M 10/44; H01M 10/48

(52) U.S. Cl. CPC H02J 7/00712; H01M 10/441; H01M 10/443; H01M 10/482; H01M 10/486; H02J 7/0013; H02J 7/0047

(57) ABSTRACT

A method for charging or discharging a battery system, wherein the battery system comprises at least two battery cells connected in parallel and/or in series, which can only be charged or discharged together. A voltage is controlled as a control variable by a current or a power as a manipulated variable. The current or the power is specified by taking into account a first state of charge-dependent characteristic curve and a second state of charge-dependent characteristic curve. The first state of charge-dependent characteristic curve and the second state of charge-dependent characteristic curve have opposite gradients, at least in sections. An apparatus for charging or discharging a battery system is also provided.

This nonprovisional application claims priority under 35 U.S.C. § 119 (a) to German Patent Application No. 10 2023 207 541.5, which was filed in Germany on Aug. 7, 2023, and which is herein incorporated by reference.

### BACKGROUND OF THE INVENTION

### Field of the Invention

The invention relates to a method and an apparatus for charging or discharging a battery system.

### Description of the Background Art

Depending on temperature, power supply duration and state of charge, Li-ion cells can only absorb a limited charging current without being damaged. This maximum current also changes with the state of health (SOH) of the Li-ion cells. Furthermore, there is the difficulty that several cells can be connected in series or in parallel in a battery system and that the cells can have different temperatures and/or states of health and/or states of charge. Therefore, it is currently necessary to know the state of charge and health of all cells in the system, as well as the coldest and warmest point at all times. This also includes the fact that temperature gradients within a cell must be known in order to actually know the coldest and warmest point in the entire battery system. These two points, together with the state of charge and health of each cell, determine the maximum possible charging current at any given time. Since a fully relaxed cell can absorb a higher current than the maximum possible continuous current for a short time, the temporal reaction of the cell to the charging current must also be known. In addition, the maximum permissible charging currents also depend on a mechanical pressure or force acting on the battery cells. Furthermore, a state of charge distribution, i.e., different states of charge, can occur within the battery system between the individual battery cells. In addition, there can also be a state of charge distribution within a battery cell. This state of charge distribution must be taken into account when selecting (controlling) the charge current, as the charge current usually depends on the state of charge. However, determining the state of charge of each individual cell with battery cells connected in parallel and the state of charge distribution within a battery cell cannot be implemented in a technically sensible way in practical operation.

A method for determining at least one control parameter for a charging device for the supply of electrical charge to a lithium-based electrical energy storage system is known from DE 10 2021 108 085 A1, for which purpose the electrical energy storage system is subjected to an electrical charging current dependent on at least one state parameter of the electrical energy storage system. In order to determine the at least one control parameter, a limit function by which an electrical limit voltage is assigned to a supplied electrical charge quantity is determined in such a way that an anode potential is greater than a specified anode potential value if the connection voltage is less than the limit voltage, wherein the specified anode potential value is greater than zero volts as compared to a Li/Li+ reference electrode.

### SUMMARY OF THE INVENTION

It is therefore an object of the invention to improve a method and an apparatus for charging or discharging a battery system.

In particular, a method for charging or discharging a battery system is provided, wherein the battery system has at least two battery cells connected in parallel and/or in series, which can only be charged or discharged together, wherein a voltage as a control variable is controlled by means of a current or a power as a manipulated variable, wherein the current or power is specified taking into account a first state of charge-dependent characteristic curve and a second state of charge-dependent characteristic curve, and wherein the first state of charge-dependent characteristic curve and the second state of charge-dependent characteristic curve have opposite gradients, at least in sections.

Furthermore, in particular, an apparatus for charging or discharging a battery system is created, wherein the battery system has at least two battery cells connected in parallel and/or in series, which can only be charged or discharged together, comprising a controller, wherein the controller is designed to control a voltage as a control variable by means of a current or power as a manipulated variable, wherein the current or power is specified taking into account a first state of charge-dependent characteristic curve and a second state of charge-dependent characteristic curve, and wherein the first state of charge-dependent characteristic curve and the second state of charge-dependent characteristic curve have opposite gradients, at least in sections.

Furthermore, in particular, a method for charging or discharging a battery system is provided, wherein the battery system has a battery cell, wherein a voltage is controlled as a control variable by means of a current or a power as a manipulated variable, wherein the current or power is specified taking into account a first state of charge-dependent characteristic curve and a second state of charge-dependent characteristic curve, and wherein the first state of charge-dependent characteristic curve and the second state of charge-dependent characteristic curve have opposite gradients, at least in sections.

An apparatus for charging or discharging a battery system is also created, wherein the battery system has a battery cell, comprising a controller, wherein the controller is designed to control a voltage as a control variable by means of a current or a power as a manipulated variable, wherein the current or power is specified taking into account a first state of charge-dependent characteristic curve and a second state of charge-dependent characteristic curve, and wherein the first state of charge-dependent characteristic curve and the second state of charge-dependent characteristic curve have opposite gradients, at least in sections.

The method and the apparatus make it possible to control charging or discharging as a whole system based on a state of charge of the battery system, in particular without having to know the states of the individual battery cells. One of the basic ideas is to use two characteristic curve dependent on the state of charges for control, wherein these two characteristic curves have an opposite gradient, at least in sections. This makes it possible to comply with limit values for electrical variables during charging and discharging, in particular when an estimate of the state of charge is subject to an error.

A voltage, current, internal resistance, and charging and discharging power are, in particular, a total voltage, a total current, a total internal resistance, and a total power of the battery system. The sizes for the individual battery cells in particular are not recorded and/or used.

In particular, it is provided that a voltage can be recorded at the battery system, wherein this voltage is used as a control variable for control.

In particular, it is provided that the characteristic curves specify maximum values (limit values) for suitable electrical quantities that must not be exceeded. By using two characteristic curves, two such quantities can be taken into account and/or used for the control process according to this method. It may be provided that during the control process, compliance with the first characteristic curve is first checked and then compliance with the second characteristic curve. Alternatively, however, it may also be provided that compliance with the second characteristic curve is first checked during the control process and then compliance with the first characteristic curve. Furthermore, compliance with both characteristic curves can also be checked at the same time.

The first state of charge-dependent characteristic curve and the second state of charge-dependent characteristic curve are determined in particular under laboratory conditions, especially in empirical experiments, and/or with the help of simulations. This can be used, for example, to determine a characteristic curve for a maximum voltage dependent on the state of charge. For example, measurements can be taken on 3-electrode laboratory cells. In addition, compressive force, thickness or high precision coulometry measurements can also be carried out. Furthermore, a specified current characteristic map can also be applied to the cell, in particular also taking into account a safety margin, and in this way a state of charge-dependent characteristic curve for the maximum voltage can be determined. A simulation can be carried out on the basis of half-cell models, for example.

Parts of the apparatus, especially the controller, can be designed individually or collectively as a combination of hardware and software, for example as program code that is executed on a microcontroller or microprocessor. However, parts may also be designed individually or collectively as an application-specific integrated circuit (ASIC) and/or field-programmable gate array (FPGA).

The characteristic curves can have opposite gradients across all states of charge. This makes it particularly easy to implement the method and the apparatus and ensures compliance with limit values at all times.

The first state of charge-dependent characteristic curve can specify a maximum voltage during charging or discharging that increases with the state of charge. This allows for a voltage to be limited during charging and discharging. This is based on the idea that if the maximum charge or discharge current is determined for each state of charge and the assumption is made that the anode potential is the limiting factor, this results in a full-cell voltage trajectory dependent on the state of charge that is independent of the temperature. In particular, this full-cell voltage trajectory then forms the first state of charge-dependent characteristic curve. This full-cell voltage trajectory increases with increasing state of charge.

The first state of charge-dependent characteristic curve can specify a maximum internal resistance during charging or discharging that increases with the state of charge. The internal resistance can be calculated on the basis of a current and an overvoltage (=external voltage, i.e., a voltage under load, minus the open-circuit voltage). The overvoltage can be estimated from a model in a known manner.

The second state of charge-dependent characteristic curve can specify a maximum current that falls with the state of charge during charging or discharging. This can limit a current during charging and discharging.

The second state of charge-dependent characteristic curve can specify a maximum power that falls with the state of charge during charging or discharging. This can limit the power during charging or discharging. The power can be a power calculated from the current and the voltage (i.e., P=U*I; with P being the power, U the voltage and I the current). In principle, however, the power can also be a power loss, which is calculated, for example, from the internal resistance and the current (i.e., P=R*I²) or from the overvoltage and the current (i.e., P=U_{Ü}*I).

It may also be provided that the first state of charge-dependent characteristic curve and/or the second state of charge-dependent characteristic curve can represent a combination of electrical quantities and/or specify limit values for such a combination of electrical quantities.

The temperature of the battery system can be recorded and/or estimated, wherein the first state of charge-dependent characteristic curve and/or the second state of charge-dependent characteristic curve are temperature-dependent, taking into account the recorded and/or estimated temperature. This allows for temperature effects to be taken into account, so that control during charging or discharging can be further improved.

The state of charge of the battery system can be estimated based on the temporal integration of the current during charging or discharging. For this purpose, a state of charge estimator integrates a current flowing during charging or discharging. This provides a balanced load that has flowed into and/or out of the battery system. Based on a starting value and a total amount of charge that the battery system can store, the current state of charge can be determined in this way. The state of charge (SOC), for example, can be specified as a percentage or in absolute terms in the unit ampere-hours (Ah) with reference to a maximum amount of charge that can be stored.

The state of charge of the battery system can be estimated based on an open-circuit voltage-state of charge (OCV/SOC) characteristic curve and/or by means of an electric battery model. The open-circuit voltage-state of charge (OCV/SOC) characteristic curve makes it possible to estimate the state of charge by measuring the open-circuit voltage in the non-loaded state of the battery system. The electric battery model makes it possible to estimate a state of charge in a known way on the basis of measurable electrical quantities (open-circuit voltage, voltage, current, internal resistance, etc.). The open-circuit voltage-state of charge (OCV/SOC) characteristic curve and/or the electric battery model are determined, for example, with the help of measurements under laboratory conditions, i.e., by empirical tests, and/or with the help of simulations.

Further features for the design of the apparatuses result from the description of the designs of the method. The advantages of the apparatuses are the same as in the design of the method. The embodiments of the method and the apparatus for charging and discharging a battery system with only one battery cell are in particular the same as for a battery system with multiple battery cells.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic representation of an example of the apparatus for charging or discharging a battery system;

FIGS. 2a, 2b, and 2c are schematic representations to illustrate the operation of an example of the method and the apparatus;

FIG. 3 results of a simulated charging process on a battery system with two battery cells connected in parallel and a control system according to the method.

### DETAILED DESCRIPTION

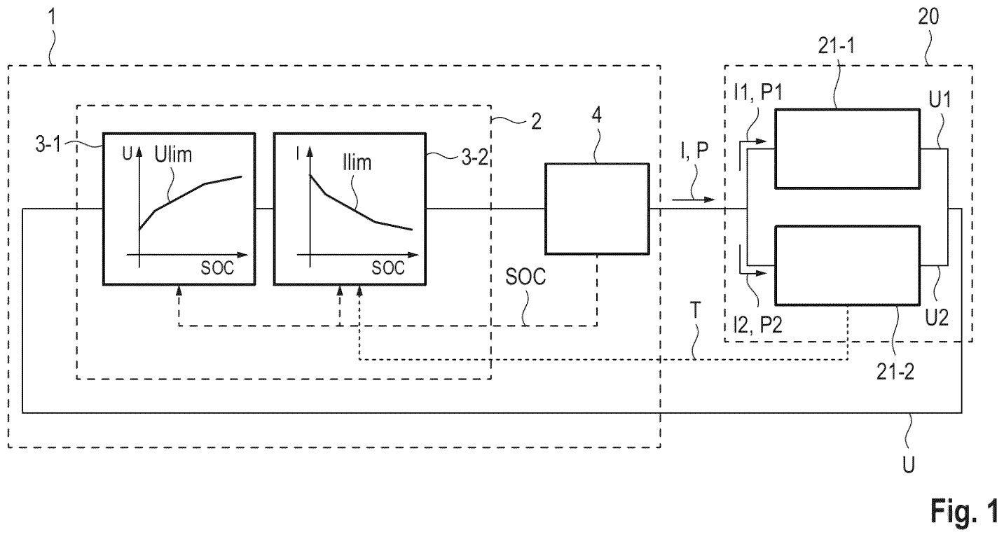

FIG. 1 shows a schematic representation of an example of the apparatus 1 for charging or discharging a battery system 20. The battery system 20 comprises two battery cells 21-x connected in parallel (alternatively in a different circuit), which, however, can only be charged and discharged together. The battery cells 21-x are Li-ion cells in particular. An apparatus for charging and discharging a battery system with only one battery cell is in principle designed in the same way as the example shown in FIG. 1, so that this will not be discussed separately.

The apparatus 1 includes a controller 2. The controller 2 is set up to control a (total) voltage U composed of the voltages U1, U2 at the battery cells 3-x as a control variable by means of a current I or a power P as a manipulated variable. The current I or the power P is divided between the currents I1, I2 or the powers P1, P2 at the individual battery cells 21-x. The voltage U and the current I or the power P refer to the battery system 20 as a whole system, i.e., the corresponding values for the individual battery cells 21-x are not known and are also not recorded. The voltage U is recorded on the battery system 20 by means of a sensor system set up for this purpose.

It is provided that the current I or the power P is specified during control, taking into account a first state of charge-dependent characteristic curve 3-1 and a second state of charge-dependent characteristic curve 3-2. The first state of charge-dependent characteristic curve 3-1 and the second state of charge-dependent characteristic curve 3-2 have an opposite gradient, at least in sections. In particular, the control process is carried out in such a way that the maximum values (limit values) specified by the characteristic curves 3-x are not exceeded.

A state of charge SOC is estimated by means of a state of charge estimator 4 of the apparatus 1. It may be provided that the state of charge SOC of the battery system 20 is estimated on the basis of temporal integration of the current I during charging or discharging. Alternatively or additionally, it may be provided that the state of charge SOC of the battery system 20 is estimated on the basis of an open-circuit voltage-state of charge (OCV/SOC) characteristic curve and/or by means of an electric battery model.

In the example shown, it is provided in particular that the first state of charge-dependent characteristic curve 3-1 specifies a maximum voltage Ulim during charging or discharging that increases with the state of charge SOC.

Furthermore, the example shown also provides in particular that the second state of charge-dependent characteristic curve 3-2 specifies a maximum current Ilim falling with the state of charge SOC during charging or discharging.

In the example shown, it is particularly provided that the characteristic curves 3-1, 3-2 have opposite gradients across all states of charge SOC.

Alternatively, it can be provided that the first state of charge-dependent characteristic curve 3-1 specifies a maximum internal resistance during charging or discharging that increases with the state of charge SOC.

Alternatively, it can be provided that the second state of charge-dependent characteristic curve 3-2 specifies a maximum power during charging or discharging that falls with the state of charge SOC.

It may be provided that a temperature T of the battery system 20 is recorded and/or estimated, wherein the first state of charge-dependent characteristic curve 3-1 and/or the second state of charge-dependent characteristic curve 3-2 are temperature-dependent, and wherein the recorded and/or estimated temperature T is taken into account. For example, it may be provided that the characteristic curves 3-x are selected or parameterized based on the recorded and/or estimated temperature T.

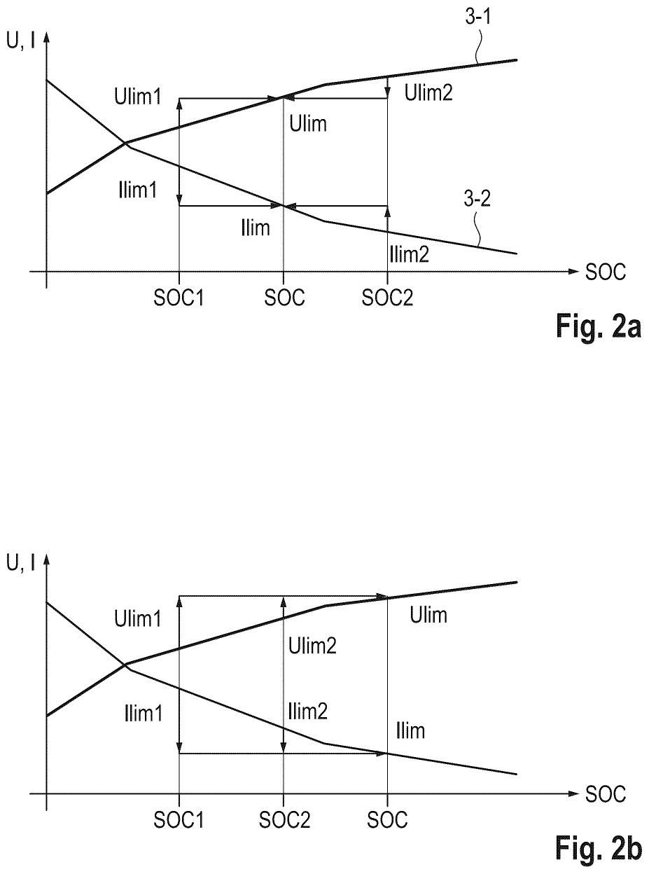

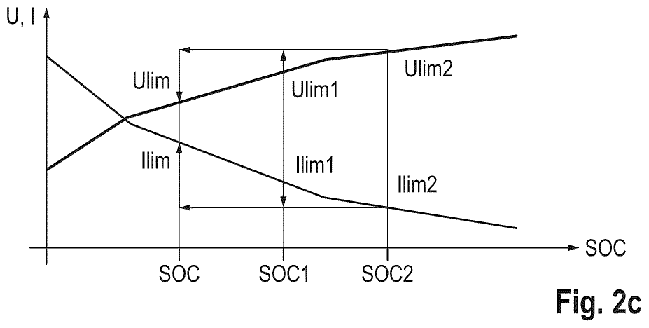

FIGS. 2a, 2b and 2c show schematic representations to illustrate the operation of an example of the method and the apparatus. Each of the three figures shows a specific case of states of charge at a single point in time.

In FIG. 2a, the state of charge estimator 4 estimates a state of charge SOC that corresponds to an average value of the state of charge SOC1, SOC2 of the two battery cells 21-x (FIG. 1). For example, due to a higher temperature in the battery cell 21-2 than the battery cell 21-1, the battery cell 21-2 has a lower internal resistance. As a result, the (total) charging current I is divided into two sub-currents of unequal size, I1 and I2. The charging current I2 is greater than the charging current I2. As a result, the state of charge SOC2 of the battery cell 21-2 rises faster than the state of charge SOC1 of the battery cell 21-1. Since the state of charge estimator 4 (FIG. 1) can only record the (total) current I or the (total) voltage U of the battery cells 21-x connected in parallel, only a resulting mean value of the state of charge SOC from the states of charge SOC1, SOC2 of the battery cells 21-x is recorded. The charge control by the charge controller 2, which releases a maximum permissible voltage Ulim based on the state of charge SOC based on the first state of charge-dependent characteristic curve 3-1, would release too high a voltage (in this case Ulim) in the case of battery cell 21-1. However, according to the method described in this disclosure, the current I would be limited to the current Ilim, which is less than Ilim1, on the basis of the second state of charge-dependent characteristic curve 3-2. Since both limits are taken into account in the control process, there would be neither a violation of the current limit nor a violation of the voltage limit as a result. On the other hand, a control system with a single characteristic curve, for example only the first state of charge-dependent characteristic curve 3-1, would have led to the maximum voltage of the battery cell 21-1 being exceeded. In the case of the battery cell 21-2, a value for the current limitation (Ilim instead of Ilim2) would initially be assumed to be too high, but the value for the voltage limitation Ulim is less than Ulim2, which also limits the resulting current I. Since both limits are taken into account in the control process, there would therefore be neither a violation of the current limit nor a violation of the voltage limit as a result. On the other hand, a control system with a single characteristic curve, for example only the second state of charge-dependent characteristic curve 3-2, would have led to the maximum current being exceeded for the battery cell 21-2.

In FIG. 2b, the state of charge estimator 4 (FIG. 1) estimates a state of charge SOC due to an error that is greater than the mean value SOC from the states of charge SOC1, SOC2 of the two battery cells 3-x. The charge control, which releases a maximum voltage U based on the state of charge SOC, would release too high a voltage Ulim in the case of battery cell 3-1 and battery cell 3-2. However, according to the method, the current is limited to Ilim due to the second state of charge-dependent characteristic curve 3-2, so that the value is smaller than Ilim1 and Ilim2. Since both limits are taken into account in the control process, there would therefore be neither a violation of the current limit nor a violation of the voltage limit as a result. On the other hand, a control system with a single characteristic curve, for example only the first state of charge-dependent characteristic curve 3-1, would have led to the maximum voltage being exceeded for both battery cells 21-1, 21-2.

In FIG. 2c, the state of charge estimator 4 (FIG. 1) estimates a state of charge SOC that is less than the mean value of the states of charge SOC1, SOC2 of the two battery cells 3-x. The charge control would initially assume too high a value for the current limitation (Ilim instead of Ilim1 and Ilim2). However, according to the method, the value of the voltage limitation Ulim is less than Ulim1 and Ulim2, which also limits the resulting current I during charging. Since both limits are taken into account in the control process, there would therefore be neither a violation of the current limit nor a violation of the voltage limit as a result. On the other hand, a control system with a single characteristic curve, for example only the second state of charge-dependent characteristic curve 3-2, would have led to the maximum current being exceeded for both battery cells 21-1, 21-2.

The scenarios shown are of an exemplary nature only and are intended to illustrate the method and apparatus described in this disclosure. In principle, the characteristic curves 3-x can also represent other quantities and/or have a different gradient.

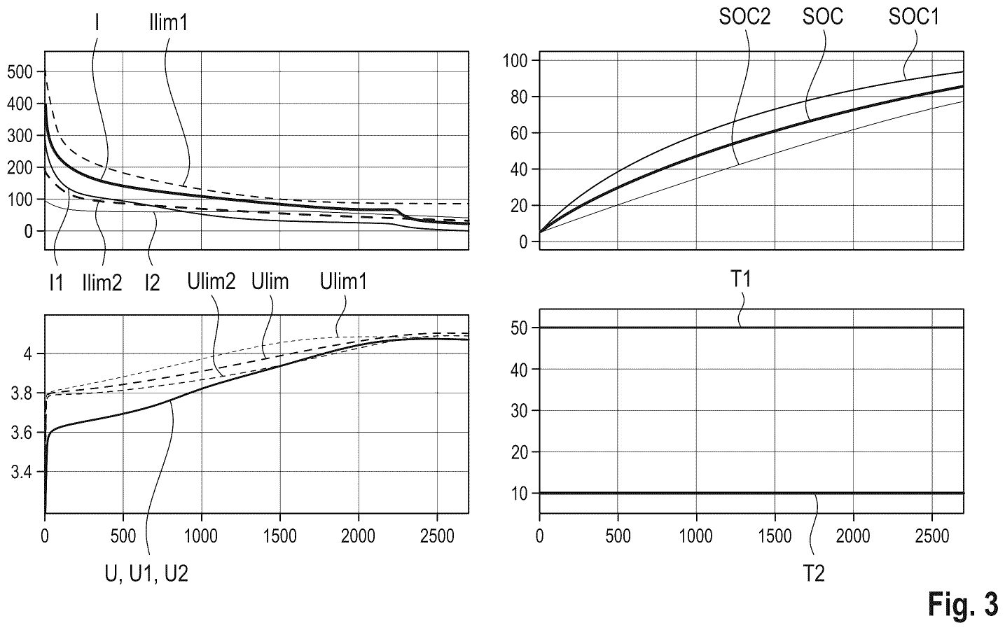

FIG. 3 shows the results of a simulated charging process on a battery system with two battery cells connected in parallel, as shown schematically in FIG. 1, and a control system according to the method. One battery cell has a temperature of 10° C., the other a temperature of 50° C. The simulation parameters used are the following:
Cell chemistry: NMC
Cell capacity: 100 Ah
Heat capacity of a cell: 2000 J/K
Isothermal boundary conditions
Heat exchange coefficient between the cells connected in parallel: 0 W/K
Starting state of charge at the beginning of the simulation: 5% (of the maximum charge quantity)
Resistance of the connecting elements of the parallel-connected cells: 0 Ohm
Contact resistances: 0 ohms
Cell internal resistance at 10° C.: 1 mOhm to 3 mOhm
Cell internal resistance at 50° C.: 0.5 mOhm to 1.5 mOhm
First state of charge-dependent characteristic curve specifies the maximum voltage Ulim (limit voltage)
Second state of charge-dependent characteristic curve specifies the maximum current Ilim (limit current)

In FIG. 3 at the top left, a (total) current I, the respective maximum currents Ilim1, Ilim2 and the currents I1, I2 of the battery cells, are each shown in A; at the top right, the (total) state of charge SOC and the states of charge SOC1 and SOC2 of the battery cells in % are shown; at the bottom left is a (total) voltage U, a respective voltage U1, U2 at the battery cells as well as a maximum voltage Ulim (limit voltage) and the maximum voltages Ulim1 and Ulim2, which result from SOC1 and SOC2 respectively, each in V, and at the bottom right is a temperature T1, T2 of the two battery cells in ° C. The quantities are each shown above the time axis with the unit seconds.

It is noted that in particular only Ulim, I and SOC as well as the temperatures are used for the control process. In particular, I1, I2, Ulim1, Ulim2, SOC1 and SOC2 are unknown in reality and serve only to illustrate the method described in this disclosure in the context of the simulation.

It can be clearly seen that the currents I1, I2 always remain below the relevant maximum current Ilim1, Ilim2 due to the control process according to the method. The voltages U1, U2 also always remain below the maximum voltage Ulim.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for charging or discharging a battery system, the method comprising:
providing the battery system with at least two battery cells connected in parallel and/or in series, which can only be charged or discharged together; and
controlling a voltage as a control variable via a current or a power as a manipulated variable, the current or the power are specified taking into account a first state of charge-dependent characteristic curve and a second state of charge-dependent characteristic curve, the first state of charge-dependent characteristic curve and the second state of charge-dependent characteristic curve having opposite gradients, at least in sections.

2. The method according to claim 1, wherein the characteristic curves have opposite gradients across all states of charge.

3. The method according to claim 1, wherein the first state of charge-dependent characteristic curve specifies a maximum voltage increasing with the state of charge during charging or discharging.

4. The method according to claim 1, wherein the first state of charge-dependent characteristic curve specifies a maximum internal resistance during charging or discharging increasing with the state of charge.

5. The method according to claim 1, wherein the second state of charge-dependent characteristic curve specifies a maximum current falling with the state of charge during charging or discharging.

6. The method according to claim 1, wherein the second state of charge-dependent characteristic curve specifies a maximum power falling with the state of charge during charging or discharging.

7. The method according to claim 1, wherein a temperature of the battery system is detected and/or estimated, wherein the first state of charge-dependent characteristic curve and/or the second state of charge-dependent characteristic curve are temperature-dependent, and wherein the detected and/or estimated temperature is taken into account.

8. The method according to claim 1, wherein a state of charge of the battery system is estimated on the basis of a temporal integration of the current during charging or discharging.

9. The method according to claim 1, wherein a state of charge of the battery system is estimated on the basis of an open-circuit voltage-state of charge characteristic curve and/or by means of an electric battery model.

10. An apparatus for charging or discharging a battery system, the battery system comprising at least two battery cells connected in parallel and/or in series, which can only be charged or discharged together, the apparatus comprising:
a controller to control a voltage as a control variable via a current or a power as a manipulated variable, the current or the power being specified by taking into account a first state of charge-dependent characteristic curve and a second state of charge-dependent characteristic curve,
wherein the first state of charge-dependent characteristic curve and the second state of charge-dependent characteristic curve have opposite gradients, at least in sections.

11. A method for charging or discharging a battery system that comprises a battery cell, the method comprising:
controlling a voltage as a control variable via a current or a power as a manipulated variable; and
specifying the current or the power taking into account a first state of charge-dependent characteristic curve and a second state of charge-dependent characteristic curve, the first state of charge-dependent characteristic curve and the second state of charge-dependent characteristic curve having opposite gradients, at least in sections.

12. Apparatus for charging or discharging a battery system comprising a battery cell, the apparatus comprising:
a controller to control a voltage as a control variable via a current or a power as a manipulated variable, the current or the power being specified by taking into account a first state of charge-dependent characteristic curve and a second state of charge-dependent characteristic curve,
wherein the first state of charge-dependent characteristic curve and the second state of charge-dependent characteristic curve have opposite gradients, at least in sections.
